(19) United States
(12) Patent Application Publication
(10) Pub. No.: US 2008/0093631 A1
(43) Pub. Date: Apr. 24, 2008

(54) Contact structure for semiconductor devices

(76) Inventors: Dong Zhi Chi, Singapore (SG); Cheng Cheh Dennis Tan, Singapore (SG); Chee Tee Chua, Singapore (SG)

Correspondence Address: KENYON & KENYON LLP, 1500 K STREET N.W., SUITE 700, WASHINGTON, DC, 20005, US

(21) Appl. No.: 11/905,909

(22) Filed: Oct. 5, 2007

Related U.S. Application Data
(60) Provisional application No. 60/828,336, filed on Oct. 5, 2006.

(51) Int. Cl. H01L 29/80; H01L 21/335

(52) U.S. Cl. 257/192; 438/191; 257/E21.448; 257/E29.315

(57) ABSTRACT

A semiconductor device has a substrate of one type of semiconductor material, such as silicon. A contact structure is formed on the substrate, and the contact structure is formed of a compound of a metal and a second type of semiconductor material, such as germanium. The contact structure according to embodiments of the present invention include a semiconductor material which a different semiconductor material forming the substrate. Higher or lower barrier height is obtained by embodiment of the invention. A method for forming a contact structure in which a substrate of one type of semiconductor material is provided. A layer of another different semiconductor material is formed on the substrate. A layer of metal is then formed on the layer of the other different semiconductor material. Upon annealing, a contact structure is formed on the substrate, which is a compound of the metal and the other different semiconductor material, onto the substrate.

### FIELD OF THE INVENTION

The present invention relates to semiconductor devices. In particular, it relates to contact structure for semiconductor devices.

### BACKGROUND OF THE INVENTION

In a Metal-Semiconductor interface, there exists a rectifying barrier known as Schottky barrier, the magnitude of this barrier called Schottky barrier height depends on the work-functions of the Metal-Semiconductor combination used. Unlike Semiconductors, work-functions are intrinsic properties of metals; little could be done but to choose the metal with the right work-functions for the desired effect: high barrier height as rectifiers or low barrier height to lower contact resistance. However, most devices require that the metal also have low resistivity for better performance. Faced with these restrictions, Metal-Semiconductor compounds, such as Metal-Silicides were introduced resulting in Silicide-Semiconductor interface which provided device manufacturers with additional choices. As a matter of fact, all high-performance CMOS devices incorporate Silicide into their structural design.

With the current interest in Optoelectronics and high-frequency devices, there is a need for even lower barrier height for ultra low contact resistance. Recently, it has been discovered that the Fermi-level of Germanium is pinned very close (˜0.1 eV) to its valence band. As such, ultra low contact resistance involving Germanide/p-Germanium interface is currently being tested and verified.

Plus the likelihood of future CMOS devices either incorporating Germanium into its substrate or adopting a Schottky-Barrier-MOS design, there is a need to further expand the idea of Silicide-Semiconductor interface.

### SUMMARY OF THE INVENTION

Embodiments of the present invention offer additional alternatives to control the barrier height in semiconductor devices. Barrier heights are successfully controlled through contact structure configured according to embodiments of the present invention.

In accordance with one aspect of the present invention, there is provided a contact structure for semiconductor devices. In one embodiment, the semiconductor device has a substrate of one type of semiconductor material, such as silicon. A contact structure is formed on the substrate, and the contact structure is formed of a compound of a metal and a second type of semiconductor material, such as germanium. The contact structure according to embodiments of the present invention therefore includes a semiconductor material, formed on a substrate which is of a different type of semiconductor material. An effect of either increased or decreased barrier height is obtained in a semiconductor device employing such a contact structure.

In accordance with another aspect of the present invention, there is provided a method for forming a contact structure for semiconductor devices. In one embodiment, a substrate of a first type of semiconductor material is provided onto which, a layer of second type of semiconductor material is formed. A layer of metal is then formed on the layer of second semiconductor material. Upon annealing, a contact structure is formed, which is a compound of the metal and the second semiconductor material, onto the substrate. The first type of semiconductor material may be silicon, the layer of second type of semiconductor material may be a layer of germanium. Upon annealing, a metal-germanide is formed on the silicon substrate as the contact structure.

Other aspects and advantages of the present invention will become apparent from the following detailed description, taken in conjunction with the accompanying drawings, illustrating by way of example the inventive concept of the present invention.

### BRIEF DESCRIPTION OF THE DRAWINGS

These and other aspects and advantages of the present invention will be described in detail with reference to the accompanying drawings, in which:

FIG. 1 is a schematic diagram showing a contact structure and forming method according to one embodiment of the present invention;

FIGS. 2A to 2D are schematic diagrams showing a contact structure of FIG. 2 when used in one type of semiconductor device;

FIGS. 3A to 3D are schematic diagrams showing a contact structure of FIG. 2 when used in another type of semiconductor device;

FIG. 4 is a chart showing experimental results of samples prepared according to one embodiment of the present invention;

FIG. 5 is a chart showing experimental results of samples prepared according to another embodiment of the present invention;

FIGS. 6A and 6B are XTEM images showing the structures of test samples used to demonstrate experimental results shown in FIG. 4;

FIGS. 7A and 7B are XTEM images showing the structures of test samples used to demonstrate experimental results shown in FIG. 5;

FIG. 8A is a chart showing XRD measurement results of the peaks integral across the Chi angle of test samples used to demonstrate experimental results shown in FIG. 4;

FIG. 8B is a chart showing XRD measurement results of the peaks integral across the Chi angle of test samples used to demonstrate experimental results shown in FIG. 5.

### DETAILED DESCRIPTION OF THE PREFERRED EMBODIMENTS

For the purpose of illustration, embodiments of the present invention will be described to structures and methods of forming the structures, which may be described as applicable in various semiconductor devices. Nevertheless, it will be understood by one skilled in the art that embodiments of the present invention are applicable to semiconductor devices which are of different types from the examples shown here.

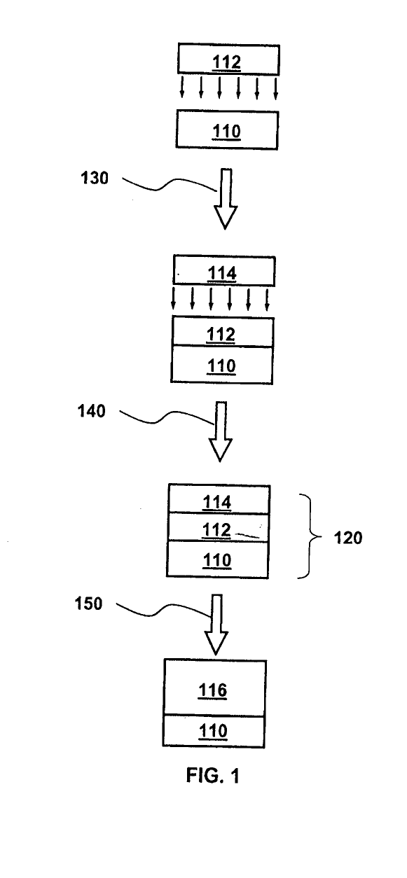

As shown in FIG. 1, a contact structure for semiconductor devices according to one embodiment of the present invention includes a substrate 110, made of a first type of semiconductor material, for example silicon. After the substrate 110 undergoes a cleaning process, a layer 112 of a second type of semiconductor material, for example germanium, is deposited on substrate 110, as shown in step 130. In the present embodiment, germanium is used here due to the similar electron affinity between germanium and silicon. Upon formation of the germanium layer 112, a metal layer 114 is deposited on germanium layer 112, as shown in step 140. The metal may be Platinum (Pt), Nickel (Ni), Palladium (Pa), alloys of these materials. The substrate 110, germanium layer 112 and metal layer 114 now form a stack 120.

Thereafter, the stack 120 is annealed, as shown in step 150, at a temperature of about 200° C. to about 700° C. during which, the metal layer 114 reacts with germanium layer 112, and form a metal-germanide layer 116 on the substrate 110. Metal-germanide layer 116 is therefore formed on substrate 110, as a contact structure. The thickness ratio of the metal layer to germanium layer may be within a range of about 0 to 20%, centered at a ratio whereby the deposited germanium and metal fully consumes each other to form the desired germanide. If the metal is platinum, the ratio is between 0.54 to 0.80 and if the metal is nickel, the ratio is between 0.47 to 0.70.

The contact structure illustrated above may be used in various applications and/or various types of semiconductor devices, as described below.

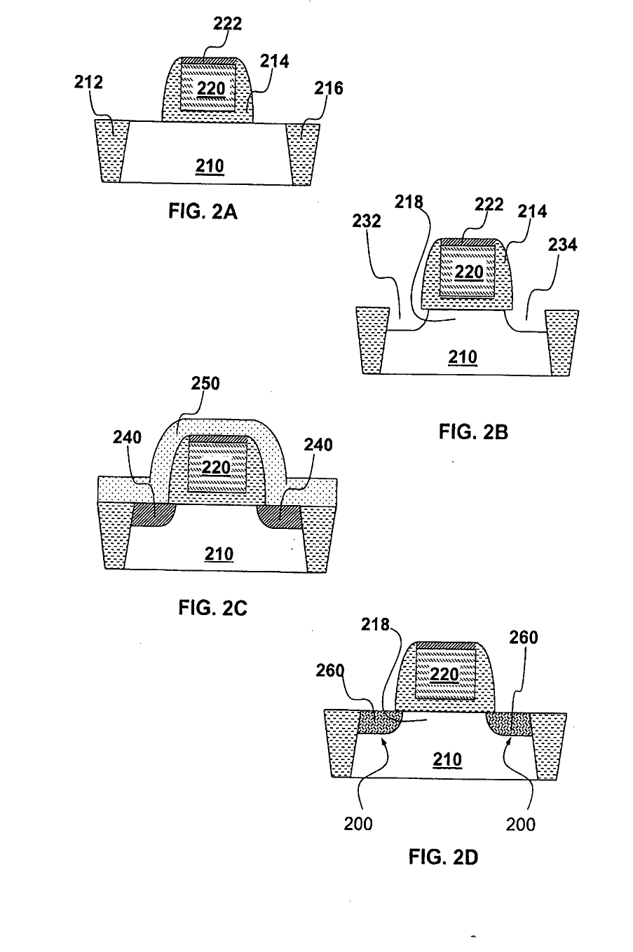

As shown in FIGS. 2A-2D, a contact structure is provided in a p-type Schottky Barrier MOS (p-SBMOS) device. In this embodiment, firstly, an n-type material is used as a substrate 210, and a basic oxide spacer etch is carried out, forming spacers 212, 214 and 216, as shown in FIG. 2A. A polysilicon (p-type) gate 220 is capped with a nitride cap 222. An etch process is then carried out where source and drain regions 232 and 234 are defined, as shown in FIG. 2B. Between source and drain regions 232 and 234 and under gate 220, there is formed a channel 218. A germanium material 240 is then deposited to fill the defined source and drain regions 232 and 234, via a selective growth process, for example a chemical vapor deposition process. Thereafter, a metal material such as platinum 250, is deposited across the structure covering gate 220, spacers 212, 214 and 216 and germanium material 240, as shown in FIG. 2C.

Upon formation of platinum 250, an annealing process is carried out, at a temperature between about 200° C. and about 700° C., to cause reaction between Pt 250 and germanium 240, to form a metal-germanide, in this case a Pt-Germanide contact 260. After the removal of the unreacted metal via a wet etch, a contact structure 200 is formed, which acts as a Schottky Barrier for the p-SBMOS device, as shown in FIG. 2D.

In the present embodiment, Pt-Germanide contact 260 serves as the source and drain, and is in direct contact with channel 218,. In SBMOS devices, the contact structure according to the present embodiment has an increased barrier height across the contact/source/drain and the channel. Having obtained an increased barrier height, a semiconductor device may be made of a reduced gate length without suffering high leakages.

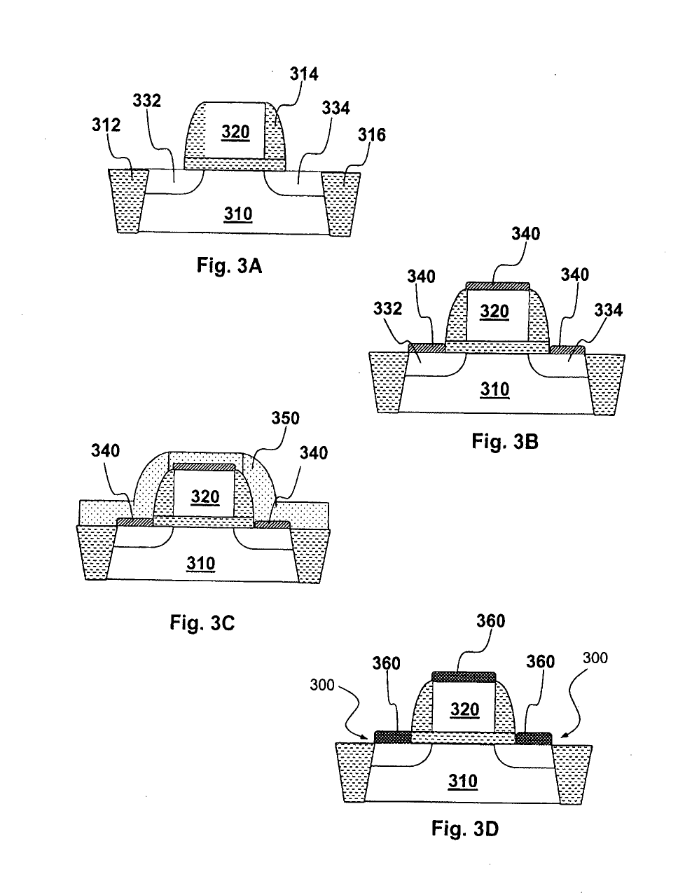

FIGS. 3A-3D show a contact structure according to another embodiment of the present invention, when used in a PMOS device. As shown in FIG. 3A, a gate 320, a source 332 and a drain 334 are formed on an n-type substrate 310, using p-type material on. Oxide spacers 312, 314 and 316 are formed subsequently. A germanium layer 340 is then selectively grown on the gate 320, source and drain 332 and 334, as shown in FIG. 3B. Thereafter, a metal material such as Pt layer 350 is deposited across the top surface of the structure covering gate 320, spacers 312, 314 and 316 and source and germanium layer 340, as shown in FIG. 3C.

Upon formation of platinum layer 350, an annealing process is carried out, at a temperature between about 200° C. and about 700° C. Upon annealing, Pt layer 350 and germanium layer 340 react with each other, and form a metal-germanide, in this case a Pt-Germanide contact 360 on gate 320, source and drain 332 and 334. After the removal of the unreacted metal, a contact structure 300 is formed, which acts as an ohmic contact for the p-MOS device, as shown in FIG. 3D.

The selective germanium growth process may be a chemical vapor deposition process, a physical vapor deposition process, a molecular beam epitaxy process, a reactive sputtering process, or any other type of thin film deposition process. The annealing process may be a furnace annealing, or a rapid thermal annealing.

It will be understood by those skilled in the relevant arts, that the present invention is not limited to embodiments illustrated above. For example, the present invention is not limited to semiconductor devices in which the substrate is made of silicon material, and the contact is made of germanide. Semiconductor devices may also be the types where the substrate is made of germanium or germanium-silicon compound, and the contact is made of a different type of semiconductor material.

As noted herein, in the preferred embodiments, the semiconductor material may include silicon carbide, but can also be selected from the group consisting of zinc selenide (ZnSe), gallium nitride (GaN), diamond, boron nitride (BN), gallium phosphide (GaP), and aluminum nitride (AlN).

The metal material may be platinum, but can also be one or more selected from the group consisting of gold (Au), nickel (Ni), platinum (Pt), palladium (Pd), silver (Ag), chromium (Cr), Aluminum (Al), or any of their alloys, for example nickel platinum (NiₓPt₁₋ₓ, where x is an integer to form various combinations of nickel and platinum). As these metals demonstrate, the high work function metal is often a low reactivity or noble metal. The metal used is chosen for its conductive/contact properties and can be nickel, platinum, palladium or any of their alloys, and these can be deposited via a variety of methods including sputtering, physical vapor deposition or chemical vapor deposition.

Experiments have been carried out, to evaluate the performances and properties of the semiconductor devices employing contact structures according to embodiments of the present invention.

In one example, a test sample is prepared by magnetron sputtering minute circular Ge pillars of 1 mm in diameter and 60 nm in thickness onto an n-Si (100) wafer substrate, after a brief dilute HF dip of the substrate to remove any native oxide. Thereafter, 35 nm and 40 nm Pt and Ni films are deposited onto the Ge pillars, without breaking vacuum or removing the shadow mask. Depositions of both films are performed at room temperature at pressures of 5×10⁻⁷ Torr or lower. The test samples with respective Pt and Ni films deposited thereon, are then subjected to Rapid Thermal Annealing (RTA) for 30 seconds at about 450° C., in nitrogen ambient. IV measurements are carried out to extract the barrier height of each of the test samples, while X-Ray Diffraction (XRD) and Transmission Electron Microscopy (TEM) techniques are used to study the formation and interface of the metal germanide on silicon stack. In order to get ohmic contact on the n-Si substrate for the IV measurement, Ti and Al of 50 nm thickness each were deposited by magnetron sputter on the back side of the substrate, after a standard dilute HF cleaning. Depositions are carried out in room temperature, at a pressure of 5×10⁻⁶ Torr or lower.

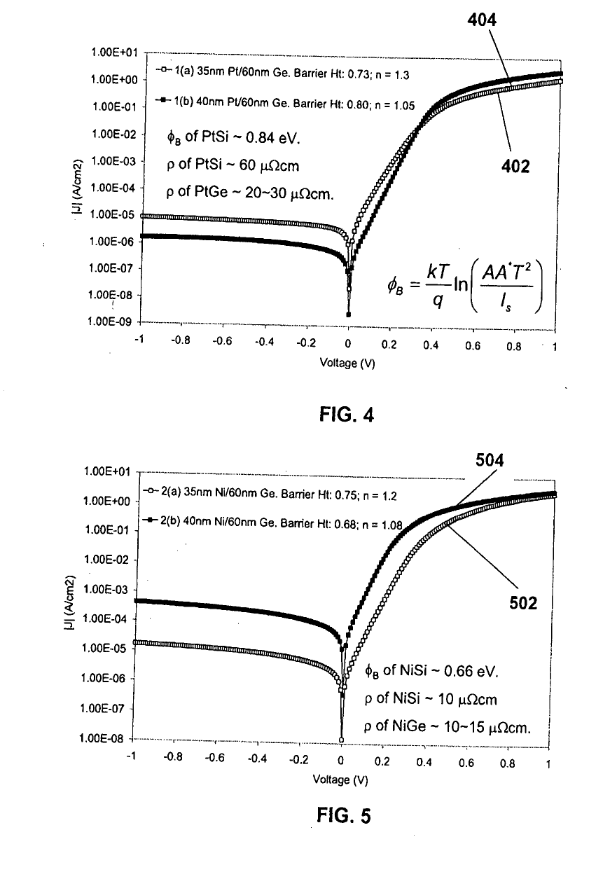

FIG. 4 shows the results of IV measurements taken from test samples which had Pt deposited onto Ge layer, and annealed to form Pt-germanide contact structure. In test sample 1(a), Pt is deposited onto Ge with a 35 nm thickness, which demonstrates a barrier height of about 0.73 eV, as shown in curve 402. In test sample 1(b), Pt is deposited onto Ge with a 40 nm thickness, which demonstrates a barrier height of about 0.80 eV, as shown in curve 404.

FIG. 5 shows the results of IV measurements taken from test samples which had Ni deposited onto Ge layer, and annealed to form Ni-germanide contact structure. Test samples 2(a) are prepared by having Ni deposited onto Ge with a 35 nm thickness, which demonstrates a barrier height of about 0.75 eV, as shown in curve 502. Test samples 2(b) are prepared by having Ni deposited onto Ge with a 40 nm thickness, which demonstrates a barrier height of about 0.68 eV, as shown in curve 504.

It can be seen from the IV measurements shown in FIG. 4, that very different Schottky barriers performance are demonstrated, even though the metal material deposited in test samples 1(a) and 1(b), are the same (i.e. Pt). Similar results are observed from IV measurements shown in FIG. 5, for test samples 2(a) and 2(b). This is interesting to note because any metal germanide/silicide should only have one value for its Schottky barrier height. In both cases, the feasibility of controlling the Schottky barrier height by stacking Germanide on Silicon substrate to achieve desired performance, i.e. a higher level of barrier height, has been demonstrated.

In test samples using Pt as the metal material (i.e. test samples 1(a) and 1(b)), it shows that a slight increase in the metal film thickness of 5 nm results in a significant increase in barrier height. The barrier height of 0.80 eV, is close to that of PtSi contact structure formed on n-Si substrate, which suggests that the slightly thicker Pt results in a layer of PtSi in between PtGe and n-Si substrate. PtGe contact structure formed on Si substrate according to embodiment of the present invention therefore has a relatively low resistivity, as compared to conventional contact structure in which PtSi contact is formed on Si substrate.

In test samples with Ni selected as the metal layer material (i.e. test samples 2(a) and 2(b)), the barrier height of 0.68 eV demonstrated in test sample 2(b) is closer to the barrier height of NiSi contact formed on n-Si substrate. Experimental results of test samples 2(a) and 2(b) suggest that the extra Ni deposited resulted in a thin layer of NiSi in between NiGe and n-Si, which lowers the barrier height.

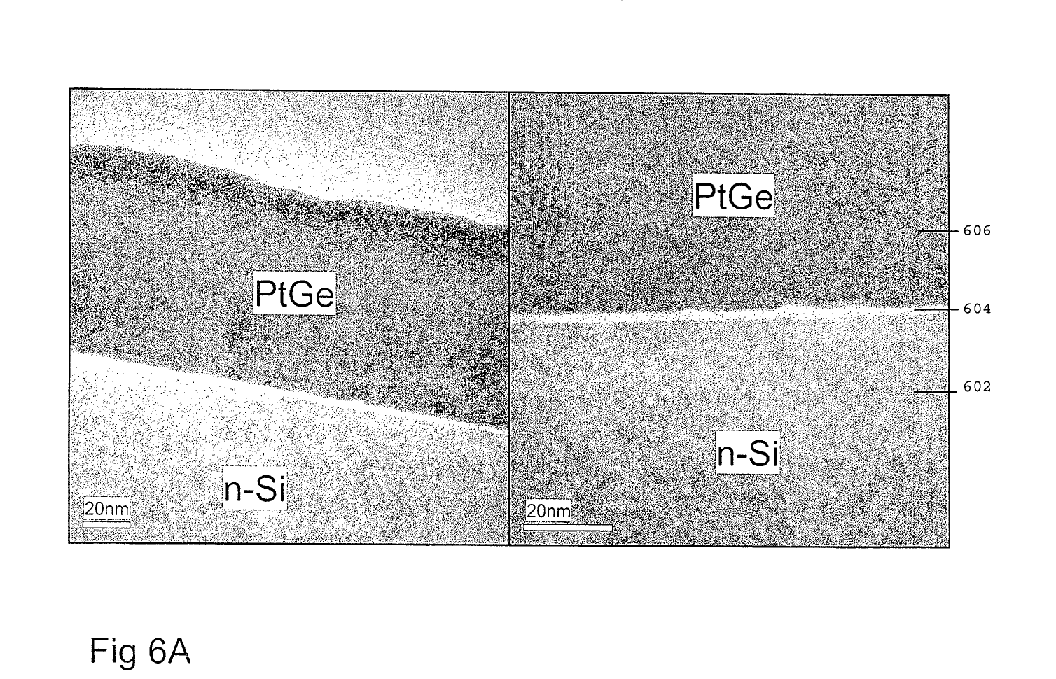

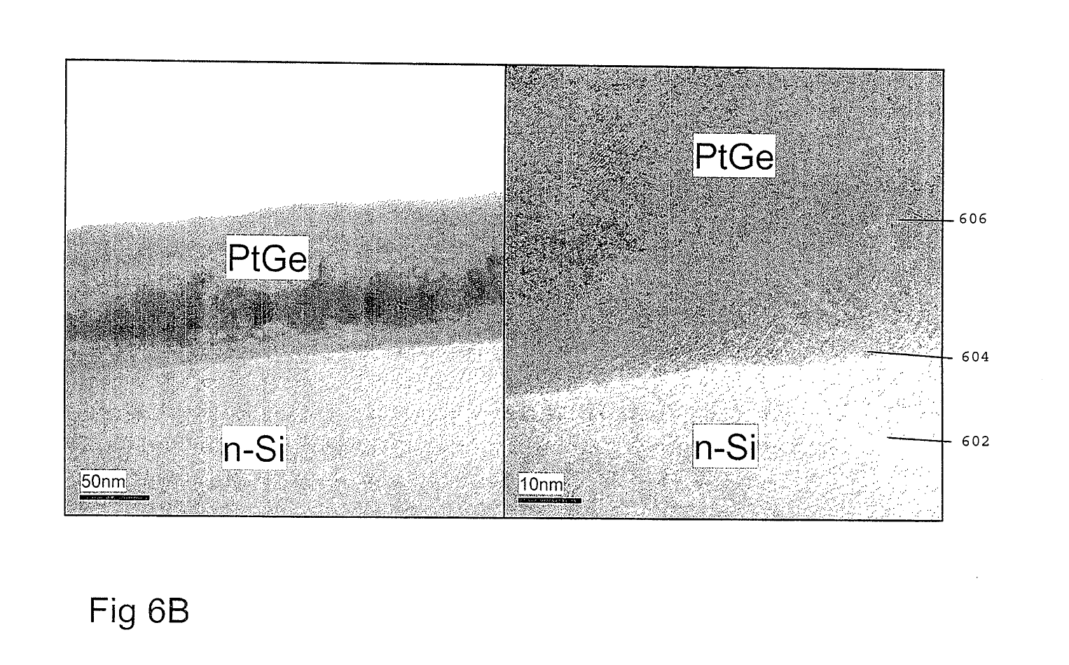

FIG. 6A is an XTEM image of test sample 1(a), and FIG. 6B is an XTEM image of test sample 1(b). From FIGS. 6A and 6B, a distinct layer 604 is observed, which is believed to be a metallic silicide, i.e. PtSi, formed in between the n-Si substrate 602 and PtGe layer 606.

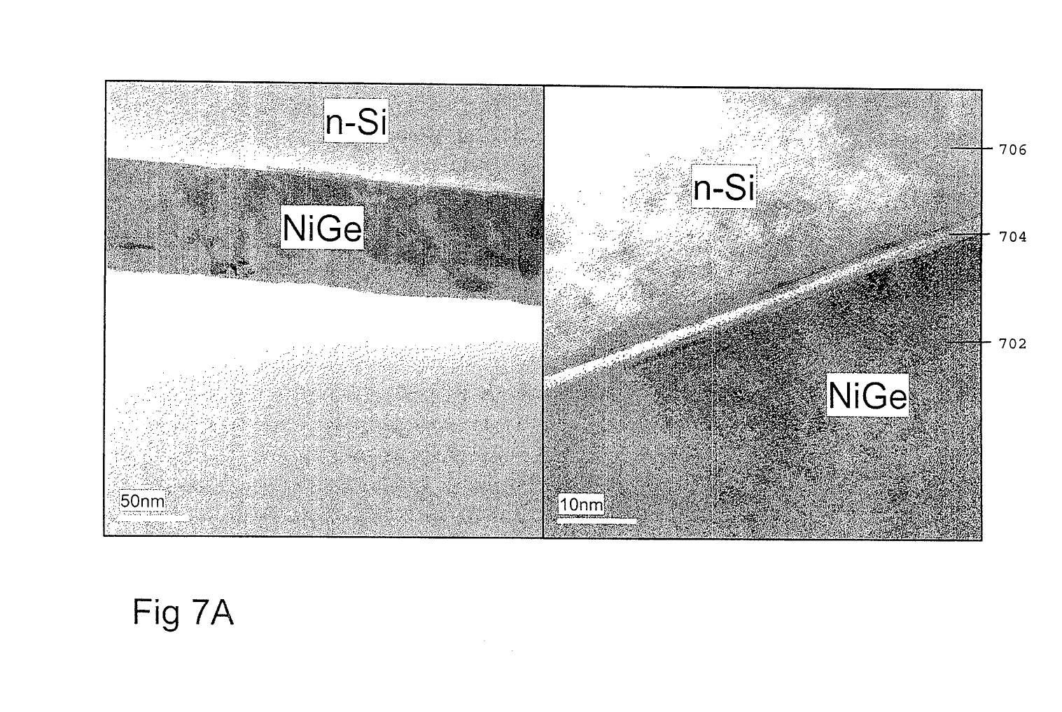

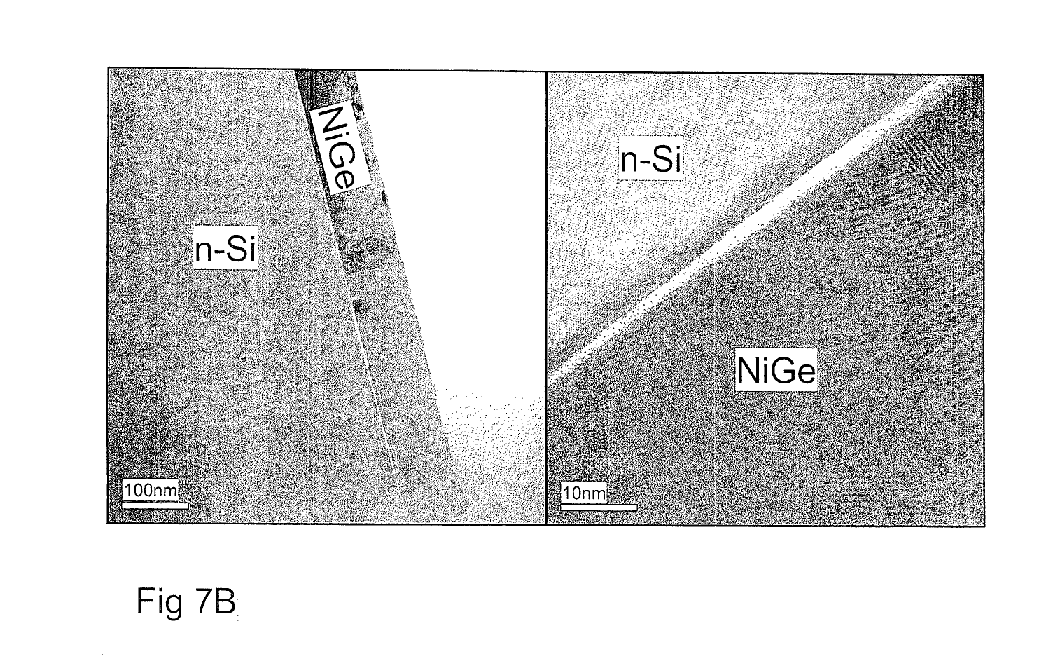

FIG. 7A is an XTEM image of test sample 2(a), and FIG. 7B is an XTEM image of test sample 2(b). From FIGS. 7A and 7B, a thin non-metallic layer 704, which is believed to be an un-reacted Ge layer, is observed in between n-Si substrate 702 and NiGe layer 706.

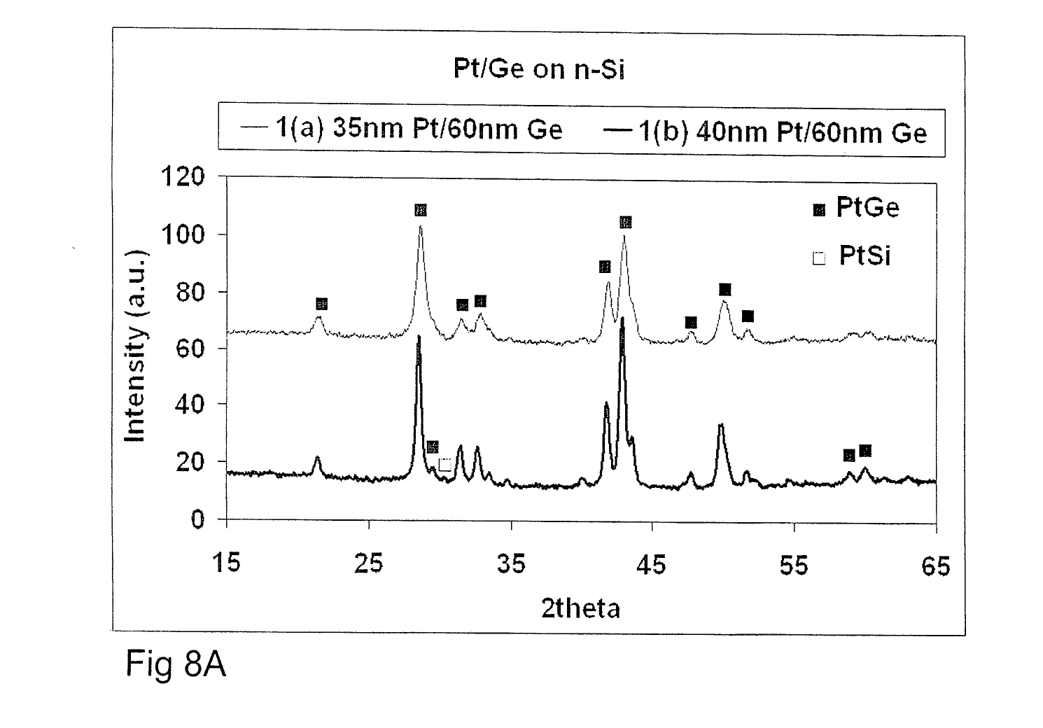

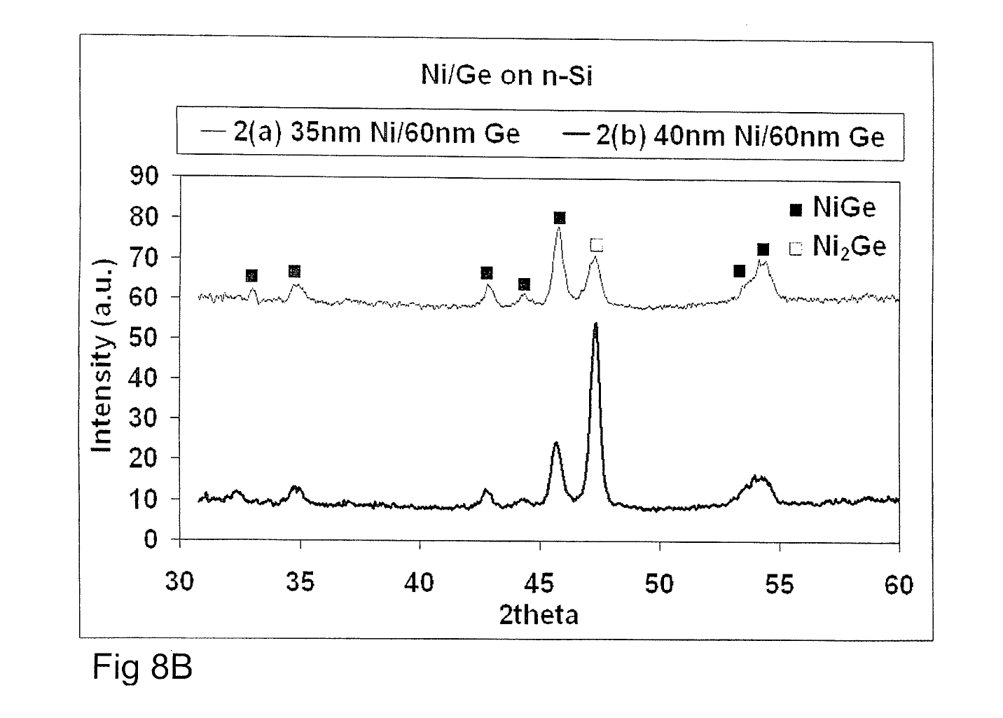

FIG. 8A shows that, there is a presence of PtSi in test sample 1(b) but not in test sample 1(a). This suggests that the thicker Pt deposition in sample 1(b) had sufficient Pt to form a layer of PtSi in between PtGe and n-Si. The results show that the barrier height across PtSi/n-Si interface is higher than that of PtGe/n-Si. However, PtSi does not have a sufficiently low sheet resistance to be considered suitable as a contact material, unlike PtGe which has low sheet resistance. Depositing a slightly thicker Pt resulted in excess Pt after PtGe formation and created a thin layer of PtSi in between PtGe and n-Si. Since the PtSi is a thin layer, it will not raise the sheet resistance substantially. The result is high barrier height (PtSi/n-Si interface)

FIG. 8B shows presence of NiGe and Ni2Ge in both test samples 2(a) and 2(b), with test sample 2(b) having more Ni2Ge. This indicates that the presence of a thin oxide layer prevented Ni from reacting with n-Si. The thin oxide layer is an unintended product due to the limitations of the processing equipment used, without which a higher barrier height would have been obtained from the NiGe on n-Si samples.

Although embodiments of the present invention have been illustrated in conjunction with the accompanying drawings and described in the foregoing detailed description, it should be appreciated that the invention is not limited to the embodiments disclosed, and is capable of numerous rearrangements, modifications, alternatives and substitutions without departing from the spirit of the invention as set forth and recited by the following claims.

1. An semiconductor device, comprising:
a substrate of a first type of semiconductor material; and
a contact structure formed on the substrate wherein the contact structure is formed of a compound of a metal and a second type of semiconductor material.

2. The device of claim 1, wherein the first type of semiconductor material is silicon and the second type of semiconductor material is germanium.

3. The device of claim 2, wherein the metal is selected from a group consisting of Au, Pt, Ni, Pd, Ag, Cr, Al and any alloy of a metal in the group.

4. The device of claim 3, wherein the compound is Pt-germanide.

5. The device of claim 4, wherein the Pt-germanide has a thickness of up to about 100 nm.

6. The device of claim 3, wherein the compound is Ni-germanide.

7. The device of claim 6, wherein the Ni-germanide has a thickness of up to about 100 nm.

8. The device of claim 1, wherein the first type of semiconductor material is germanium and the second type of semiconductor material is silicon.

9. The device of claim 1, having a gate length of about below 35 nm.

10. The device of claim 1, wherein the substrate comprises:
a source region;
a drain region;
and a channel between said source region and said drain region, wherein the contact structure is formed on the source region and the drain region in direct contact with the channel.

11. The device of claim 10, wherein the contact structure serves as the source and the drain.

12. A method of forming a semiconductor device, comprising:
providing a substrate of a first type of semiconductor material;
forming a first layer of a second type of semiconductor material on the substrate;
forming a second layer of a metal material on first layer; and
annealing the first layer and the second layer to form a compound of the metal material of the second layer and the second type of semiconductor material of the first layer wherein the compound forms a contact structure on the substrate.

13. The method of claim 12, wherein the first type of semiconductor material is silicon and the second type of semiconductor material is germanium.

14. The method of claim 13, wherein the metal is selected from a group consisting of Au, Pt, Ni, Pd, Ag, Cr, Al and any alloy of a metal in the group.

15. The method of claim 14, wherein the compound is Pt-germanide.

16. The method of claim 15, wherein the Pt-germanide has a thickness of up to about 100 nm.

17. The method of claim 15, wherein a thickness ratio of the Pt and the germanium is between about 0.54 to 0.80.

18. The method of claim 14, wherein the compound is Ni-germanide.

19. The method of claim 18, wherein the Ni-germanide has a thickness of up to about 100 nm.

20. The method of claim 18, wherein a thickness ratio of the Ni and the germanium is between about 0.47 to 0.70.

21. The method of claim 12, wherein the first type of semiconductor material is germanium and the second type of semiconductor material is silicon.

22. The method of claim 12, having a gate length of about below 35 nm.

23. The method of claim 12, wherein the substrate has a source region, a drain region and a channel therebetween, further comprising:
forming the contact structure on the source region and the drain region in direct contact with the channel.

24. The device of claim 23, wherein the contact structure serves as the source and the drain.
